(19) United States
(12) Patent Application Publication
(10) Pub. No.: US 2024/0419065 A1
(43) Pub. Date: Dec. 19, 2024

(54) METHOD AND APPARATUS FOR MASK REPAIR

(71) Applicant: Carl Zeisss SMT GmbH, Oberkochen (DE)

(72) Inventors: Christian Felix Hermanns, Frankfurt (DE); Petra Spies, Mainz (DE); Daniel Rhinow, Frankfurt (DE); Maximilian Rumler, Darmstadt (DE)

(21) Appl. No.: 18/817,349

(22) Filed: Aug. 28, 2024

Related U.S. Application Data
(63) Continuation of application No. PCT/EP2023/054967, filed on Feb. 28, 2023.

(30) Foreign Application Priority Data
Mar. 1, 2022 (DE) 102022202061.8

(51) Int. Cl. G03F 1/72; G03F 1/78; G03F 7/00; G03F 7/20

(52) U.S. Cl. CPC G03F 1/72; G03F 1/78; G03F 7/2004; G03F 7/70033

(57) ABSTRACT

The present invention relates to methods, to an apparatus and to a computer program for processing of an object for lithography.

A method of processing an object for lithography comprises: providing a first gas comprising first molecules; providing a particle beam in a working region of the object for removal of a first material in the working region, based at least partly on the first gas. The first material may comprise chromium and nitrogen. In addition, the first material may comprise at least 5 atomic percent of nitrogen, preferably at least 10 atomic percent of nitrogen, especially preferably at least 20 atomic percent of nitrogen.

### CROSS-REFERENCE TO RELATED APPLICATIONS

This application is a continuation of and claims benefit under 35 U.S.C. § 120 from PCT Application No. PCT/EP2023/054967, filed on Feb. 28, 2023, which claims the priority of the German patent application DE 10 2022 202 061.8, entitled “Verfahren und Vorrichtung zur Maskenreparatur,” which was filed at the German Patent and Trade Mark Office on Mar. 1, 2022. The entire contents of each of these earlier applications are incorporated herein by reference.

### TECHNICAL FIELD

The present invention relates to methods, to an apparatus and to a computer program for processing of an object for lithography. More particularly, the present invention relates to a method of removing a material, to a corresponding apparatus and to a method of lithographic processing of a wafer, and to a computer program for performing the methods.

### BACKGROUND

In the semiconductor industry, increasingly smaller structures are produced on a wafer in order to ensure an increase in integration density. Among the methods used here for the production of the structures are lithographic methods, which image these structures onto the wafer. The lithographic methods may comprise, for example, photolithography, ultraviolet (UV) lithography, DUV lithography (i.e. lithography in the deep ultraviolet spectral region), EUV lithography (i.e. lithography in the extreme ultraviolet spectral region), x-ray lithography, nanoimprint lithography, etc. Masks are usually used here as objects for lithography (e.g. photomasks, exposure masks, reticles, stamps in the case of nanoimprint lithography, etc.), which comprise a pattern in order to image the desired structures onto a wafer, for example.

In the course of a lithographic method, a mask may be subject to high physical and chemical stresses (for example on mask exposure, mask cleaning, etc.). Accordingly, high demands are made on the stability of the mask materials, which may become even harsher with the progression of technical development in the lithography.

Since mask errors generally cannot generally be ruled out in complex mass production, however, the mask materials may also form as mask errors on the mask (for example as defects, excess material, malformed material, overlying particles, etc.).

It is generally known that mask errors can be remedied or repaired, for example via a particle beam-based etching process. However, existing methods of mask repair consider only a limited number of mask materials.

The problem addressed by the present invention is therefore that of specifying methods and apparatuses that optimize the processing of objects for lithography.

### SUMMARY

This general aspect is at least partly achieved by the various aspects of the present invention.

A first aspect of the invention relates to a method of processing an object for lithography. The method in the first aspect comprises providing a first gas comprising first molecules. The method further comprises providing a particle beam in a working region of the object for removal of a first material in the working region, based at least partly on the first gas. The first material may comprise chromium and nitrogen. In addition, the first material may comprise at least 1 atomic percent (at %) of nitrogen, preferably at least 5 atomic percent (at %) of nitrogen, more preferably at least 10 atomic percent of nitrogen, especially preferably at least 20 atomic percent of nitrogen.

The invention addresses the problem of removing materials on an object for lithography that are designed to be resistant to removal under chemical and/or physical stress.

Recently established chromium-containing mask materials have been designed specifically with a particular nitrogen content in order to meet current and future demands. The nitrogen content may be increased stoichiometrically here with respect to the established chromium-containing mask materials (for example beyond the degree of a nitrogen contamination). By virtue of that particular nitrogen content, the mask materials may have elevated chemical stability with respect to the demands of lithography. These nitrogen-containing mask materials may, for example, account for a layer of a mask (for example a layer of a pattern element).

For example, chromium-containing material may have been specifically designed with a high nitrogen content of at least 1 atomic percent (at least 5 at %, at least 10 at % and/or at least 20 at %), in order to explicitly prevent the removal of this chromium-containing material under chemical/physical influences. The high nitrogen content may also be designed such that it prevents removal/wear of the chromium-containing material even under sustained or regular chemical/physical stress. These types of resistant chromium-containing materials are typically designed for the extreme conditions in lithography methods under which the object may be used for lithography. For example, the object may be exposed to a (damaging) plasma during a lithography method. For example, it may be necessary for a lithography method to expose the object to a hydrogen environment (for example for prevention of defects). In the case of lithographic exposure of the object, there may be release of a (parasitic) high-reactivity hydrogen plasma with free hydrogen radicals that can act on the material of the object. The plasma constitutes a high degree of chemical/physical stress on the object and can cause removal of material and damage to the material of the object (for example in a similar manner to plasma etching). However, the material-removing effect is undesirable in the lithography object, since this can adversely affect the properties of the object and hence the quality of the lithography method. Therefore, the high nitrogen content in the chromium-containing material may be (explicitly) designed in order to assure high resistance of the first material to the material-removing effect of a plasma (for example especially of the high-reactivity hydrogen plasma). Moreover, the object may be subjected to numerous other mechanical/chemical influences in lithography, which can damage the object (for example in combination with the effect of plasma). For example, the other damaging influences may include severe temperature fluctuations, exposure to radiation, and chemical reactions of the object with purge gases. The high nitrogen content is therefore typically designed to fundamentally counteract the totality of the damaging material-removing effects in lithography, such that mechanical/chemical wear and removal of the chromium-containing material is made more difficult.

The inventors have recognized that this material too can be removed in a particle beam-induced manner in order to correct any defects caused by excess material. The basis of the inventive concept is accordingly to remove materials that are specifically designed to be resistant to removal via a particle beam-based process. The inventors have hit on the unexpected finding that a chromium-containing material having a high nitrogen content of at least 1 atomic percent (at least 5 atomic percent, at least 10 at %, and/or at least 20 at %) can be removed with the aid of a provided gas and a provided particle beam (for example via particle beam-induced etching). This was a surprising finding to the inventors since it was not foreseeable that the first material—resistant to the aggressive conditions of the lithography—could be processed in a particle beam-based manner or even removed (for example without the use of a plasma, which is known to be able to etch the lithography object). In addition, it was unexpected to the inventors in view of the resistant first material that, in the case of particle beam-based removal of the first material, the provision of a gas comprising first molecules is sufficient in principle. There is not necessarily any need in accordance with the invention to resort to a complex gas mixture (for example comprising different types of molecules designed for the resistant material). This can ensure that complexity in particle beam-reduced removal is reduced, as a result of which, for example, easier process control in the method according to the invention is possible (since, for example, the providing of a single gas constitutes a lesser demand on technical implementation than the providing of a gas mixture of, for example, two or more different gases). The invention accordingly enables processing of lithography objects including resistant materials (for example with a high nitrogen content).

The unit “atomic percent”, as described herein, may relate to a molar proportion of the corresponding material, where atomic percent indicates, for example, the relative number of particles (e.g. nitrogen atoms) in relation to the total number of particles of the substance (for example total number of atoms of the first material). The atomic percentage may be detected, for example, via secondary ion mass spectrometry, SIMS, and/or Auger electron spectroscopy and/or x-ray photoelectron spectroscopy, XPS (and also, for example, via photoelectron spectroscopy, PES).

The object for lithography as described herein may comprise a lithography mask. The lithography mask may be designed such that it can be used in lithography for the production of semiconductor-based chips (for example on exposure of a semiconductor-based wafer). The lithography mask may also include any type of lithography mask that can image an image based on a source of electromagnetic radiation (of any wavelength) and a pattern encompassed in the lithography mask. The image may comprise a transformation of the pattern. The lithography mask may comprise, for example, an EUV mask, a DUV mask, a UV mask, an x-ray lithography mask, a binary mask, a phase-shifting mask, etc. In addition, the lithography mask may also comprise a nanoimprint lithography stamp, or a lithography mask, that can image a pattern based on a source of particles.

The working region specified herein may comprise a local region of the object for lithography. However, it is also conceivable that the working region comprises the entire object for lithography. The working region may also include any areal dimension, shape and/or geometry. For example, the working region may be within an order of magnitude associated with a particular measurement of the object. For example, the particular measurement may comprise a critical dimension CD of a pattern element of the object. The critical dimension CD may comprise, for example, a defined structure width of the pattern element or else a defined distance between two (characteristic) pattern elements. The working region may, for example, form an area A over the critical dimension CD of the pattern element (for example, A may correspond to a function of the critical dimension CD, with A=f(CD); for example, A may be proportional to the critical dimension). In addition, the first material may be removed within the working region such that the first material is not necessarily removed over the entire area of the working region, but is removed (locally) in a subregion of the working region. Alternatively, the removing within the working region can be carried out such that the first material is removed over the entire area of the working region. In addition, the first gas may be provided in a controlled manner in a subregion of the working region (for example via a locally positionable gas conduit with a gas nozzle). It is likewise possible for the particle beam to be provided in that it is directed onto a subregion of the working region such that the particles of the particle beam are incident on the subregion. In addition, the method may comprise specific local control and/or focusing of the particle beam in the subregion or within the working region (in order, for example, to locally control reaction of the particle beam-induced etching).

The method in the first aspect as described herein is fundamentally also conceivable with a different nitrogen content of the first material, e.g. a nitrogen content of <5 atomic percent or even <1 atomic percent or >50 atomic percent. Correspondingly, a further aspect of the invention may comprise the removing of the first material with the first gas provided and the particle beam provided, wherein the further aspect may comprise at least one more of the features described herein, without being restricted to the nitrogen content of the first material.

In addition, the inventors have recognized that the method described herein is also conceivable for a material as first material that includes a different element (e.g. a different metal) rather than chromium (or in addition to chromium). The first material may accordingly be regarded as a nitrogen-based material (e.g. a nitride-based material, e.g. a metal nitride). For example, the first material, rather than chromium, may comprise at least one of the following: niobium, titanium and/or tantalum. The first material here may comprise, for example, niobium nitride (e.g. NbN, Nb₂N, Nb₄N₃) and/or titanium nitride (e.g. TiN), and may be removed by the method described herein. The nitrogen content of niobium nitride and of titanium nitride may correspond here to the nitrogen contents described herein in the first material.

In one example, in the method in the first aspect, the first material is capable of absorbing radiation associated with the object. For example, this radiation associated with the object may comprise electromagnetic radiation with a particular wavelength which may be used in a lithography method for which the object is designed. For example, the radiation associated with the object may correspond to an exposure radiation for the object in the lithography method. The particular wavelength of the exposure radiation may be regarded as the lithography wavelength of the object. In one example, the lithography object comprises an EUV mask for an EUV lithography method, wherein the lithography wavelength (i.e. the wavelength of the exposure radiation) in this case may be 13.5 nm. In addition, the radiation may relate, for example, to a DUV lithography method (with, for example, lithography wavelength 193 nm or 248 nm), an i-line lithography method (with, for example, lithography wavelength 265 nm), or any other lithography method (with, for example, a different lithography wavelength) depending on the object.

In one example, the first material has an intrinsic material parameter which can be used to conclude a significant (e.g. high) absorption of the lithography wavelength of the object (e.g. a coefficient of absorption, a magnitude of absorption, an imaginary part of the refractive index of the first material). In addition, the first material may comprise a material which is typically present in the object in order to absorb the lithography wavelength (e.g. a material corresponding to an absorption layer (for example to a pattern element) of the object).

In a further example, the first material has not just one intrinsic material parameter per se that can be used to conclude a significant absorption. In addition, the first material may be geometrically configured such that it can effectively absorb the radiation associated with the object in a local area of the object. For example, the first material, in a (local) area of the object, may be formed geometrically such that it causes significant absorption of radiation of the lithography wavelength via the absorbing material property thereof and the geometric structure thereof. In this case, the first material in the (local) area may make an imaging contribution in a lithography method since there is an actual (i.e. effective) absorption of the radiation of the lithography wavelength. The geometry of the first material may be defined, for example, via the layer thickness of the material, or via a distance that would be covered by radiation of lithography wavelength in a lithography method through the first material (e.g. an absorption distance). The absorption distance may take account, for example, of the optical diffraction of the radiation of lithography wavelength or a vector of incidence of the exposure radiation. For example, the method may comprise not removing a very thin layer of an absorbing material (i.e. an intrinsically absorbing material), since that thin layer in geometric terms is unable to significantly absorb the radiation of lithography wavelength and hence does not make an actual (i.e. effective) imaging contribution in a corresponding lithography method. For example, significant absorption may be defined or calculated by the layer thickness or absorption distance of the first material. The layer thickness of the first material may be at least 20 nm, preferably at least 35 nm, more preferably at least 50 nm, most preferably at least 60 nm. However, the layer thickness of the first material may alternatively be less than 60 nm, for example less than 50 nm or less than 35 nm. Significant absorption may also be described in that the intensity of the radiation of lithography wavelength is attenuated by 70%, preferably 80%, most preferably 90%, in a lithography method (across the first material).

In one example, in the method in the first aspect, the first material corresponds to a layer material of a pattern element of the object. In one example, in the method, the layer material corresponds to a material of an absorption layer of the pattern element. The absorption layer may comprise the layer of the pattern element which is explicitly set up for the absorbing of the radiation of lithography wavelength.

In one example, in the method, the first material comprises at least 10 atomic percent of chromium, preferably at least 20 atomic percent of chromium, most preferably at least 30 atomic percent of chromium. In a further example, in the method, the first material comprises at least 10 atomic percent of chromium oxide, preferably at least 20 atomic percent of chromium oxide, most preferably at least 30 atomic percent of chromium oxide. In a further example, in the method, the first material comprises at least 2 atomic percent of chromium in a metallic compound, preferably at least 3 atomic percent of chromium in a metallic compound, most preferably at least 4 atomic percent of chromium in a metallic compound. The atomic percentage may be detected, for example, via secondary ion mass spectrometry, SIMS, and/or Auger electron spectroscopy and/or x-ray photoelectron spectroscopy, XPS (and also, for example, via photoelectron spectroscopy, PES). In particular, the molar proportion of metallic chromium can be detected via an XPS analysis.

In one example, in the method in the first aspect, the first material comprises a chromium nitride. The chromium nitride may comprise, for example, CrN and/or Cr₂N. Chromium nitride may be notable for high hardness and extreme corrosion resistance. The inventors have recognized that chromium nitride, or a material having a chromium nitride content, can be processed or removed by the method according to the invention. Chromium nitride can be detected, for example, via standard physical/chemical analysis methods (for example via x-ray spectroscopy). For example, CrN may have a refractive index n of 0.9295 and an absorption coefficient kβ of 0.0336. For example, Cr₂N may have a refractive index n of 0.9272 and an absorption coefficient kβ of 0.0376.

In one example, the first gas may be regarded as a main etching gas for the removal of the first material. The first gas here may be designed such that it has a substantial influence on the etching characteristics of the first material. For example, the molecules of the first gas may be chosen such that they bring about an etching/removing effect on the first material. Alternatively, the first molecules may also be chosen such that they bring about an etching/removing effect on the first material in conjunction with a reaction which is induced by the particle beam.

In one example, in the method in the first aspect, the first molecules of the first gas comprise at least one halogen atom. The inventors have recognized that a gas especially suitable for the removing of the resistant first material (for example having the highest nitrogen content described herein) is one comprising molecules including a halogen. Such a first gas (i.e. etching gas) in conjunction with the particle beam provided can remove the resistant first material advantageously in a technically desirable manner. For example, such a first gas can avoid removal residues, long etching times, and inhomogeneous material removal in the method in the first aspect.

In one example, in the method in the first aspect, the first molecules comprise a halogen compound. For example, the halogen compound may comprise a chemical compound including at least one halogen atom, where the halogen atom enters into a chemical compound with at least one further chemical component (for example any further chemical element/atom and/or a further chemical substance group/substance compound, etc.). In one example, the halogen compound may comprise exclusively halogens of the same type (for example, the first molecules may comprise F₂, Cl₂, Br₂, etc.).

In one example, in the method in the first aspect, the halogen compound comprises a nitrosyl halide and/or a nitryl halide. In one example, in the method in the first aspect, the nitrosyl halide comprises at least one of the following: nitrosyl chloride, NOCl, nitrosyl fluoride, NOF, nitrosyl bromide, NOBr. In a further example, in the method in the first aspect, the nitryl halide comprises at least one of the following: nitryl chloride, ClNO₂, nitryl fluoride, FNO₂. The inventors have recognized here that such first molecules too (e.g. nitrosyl halide or nitryl chloride), in the context of the method in the first aspect, can advantageously remove the resistant first material in a technically desirable manner.

In one example, the halogen compound comprises a noble gas halide. For example, the noble gas halide may comprise a chemical compound including at least one halogen atom and at least one noble gas atom.

In one example, the noble gas halide comprises at least one of the following: xenon difluoride, XeF₂, xenon dichloride, XeCl₂, xenon tetrachloride, XeCl₄, xenon tetrafluoride, XeF₄, xenon hexafluoride, XeF₆. The inventors have recognized here that such noble gas halides too (e.g. xenon difluoride in particular), in the context of the method in the first aspect, can advantageously remove the resistant first material in a technically desirable manner.

In a further example, the first molecules comprise a quadrupole moment (or a multipole moment with at least four poles) of greater than zero. For example, xenon difluoride may have a quadrupole moment greater than zero.

In one example, the halogen compound comprises an interhalogen compound (e.g. an interhalogen). For example, the interhalogen compound may include a chemical compound of at least two different halogens with one another. The inventors have recognized that interhalogens are also suitable as first molecules of the first gas for removal of the resistant first material in a technically desirable manner. For example, the interhalogen compound may comprise at least one of the following: ClF, ClF₃, BrF, BrF₃, ICl, ICl₃, BrCl, IF, IF₃, IBr, IBr₃.

In a further example, the first gas comprises a combination of the first molecules specified herein. The first gas may also be regarded as a combination of different gases with different first molecules. For example, the first gas may comprise any combination of one or more nitrosyl halides, nitryl halides, noble gas halides and/or interhalogens as first molecules.

For example, the first gas may comprise a nitrosyl halide and a noble gas halide. In this case, for example, the first gas may comprise NOCl and/or NOF as nitrosyl halide and XeF₂ as noble gas halide.

For example, the first gas may comprise a nitryl halide and a noble gas halide. In this case, for example, the first gas may comprise ClNO₂ and/or FNO₂ as nitryl halide and XeF₂ as noble gas halide.

For example, the first gas may comprise a nitrosyl halide and a nitryl halide. In this case, for example, the first gas may comprise NOCl and/or NOF as nitrosyl halide and ClNO₂ and/or FNO₂ as nitryl halide.

In one example, the first molecules comprise polar molecules. It has been found that polar molecules having a dipole moment may be suitable in principle for the process. In a further example, the first molecules may also comprise nonpolar molecules. The invention is also based on the concept that nonpolar molecules without a dipole moment may also be suitable in principle for the process. In an additional example, the first molecules comprise triatomic molecules. According to the invention, there is not necessarily any need for complex compounds having more than three atoms per molecule for a suitable method in the first aspect.

In one example, in the method in the first aspect, a first dipole moment associated with the first molecules comprises at least 1 D (D: debye), preferably at least 1.5 D, more preferably at least 1.7 D, most preferably at least 1.8 D. In a further example, in the method, the first dipole moment comprises at least less than 2.5 D, preferably at least less than 2.3 D, more preferably at least less than 2.1 D, most preferably at least less than 2 D. The inventors have recognized that probability of adhesion of the (first) molecules to a surface depends on their dipole moment (for example, the probability of adhesion may be proportional to the dipole moment). The invention makes use of this effect in the removal of the first material. In the particle beam-based removal (e.g. particle beam-induced etching), what is typically required is a defined (local) gas concentration of the first gas (i.e. the etching gas) over a particular period of time, in order to allow the removal reaction to run in a defined manner. It may therefore be helpful to specifically adjust the defined (local) gas concentration. On account of chemical and/or physical interactions in the removing of the first material, however, the defined (local) gas concentration may vary to a technically undesirable degree. For example, this may comprise (local) depletion of the first gas within the working region, such that the process of removing the first material is influenced in an unwanted manner. The inventors have recognized here that the use of first molecules having the dipole moments described herein can imply improved conditions of adhesion probability of the first molecules on a surface (for example the surface of the first material). This can enable, for example, optimized coverage of the first molecules in the working region of the object. By means of this technical effect, it is therefore possible to achieve optimized conditions in the configuration of the defined (local) gas concentration, which can optimize the removal of the first material.

In one example, the method in the first aspect further comprises providing a second gas comprising second molecules, wherein the removing of the first material is further based at least partly on the second gas. The second gas described herein may be regarded in this context as additive gas in relation to the main etching gas (i.e. the first gas). The second gas can further influence the removing or particle beam-induced etching of the first material as additive gas and, for example, more accurately adapt process parameters/results (e.g. etch rate, anisotropy factor, selectivity, sidewall angle, surface roughness, etc.). In principle, the features described herein for the providing of the first gas may also be applicable to the providing of the second gas, and vice versa.

In one example, in the method in the first aspect, a first dipole moment associated with the first molecules and a second dipole moment associated with the second molecules differ from one another by not more than 0.1 D, preferably not more than 0.08 D, more preferably not more than 0.07 D, most preferably not more than 0.06 D. This example is based on the idea that the first molecules of the first gas (i.e. of the main etching gas) have a similar dipole moment to the second molecules of the second gas (i.e. of the additive gas). The inventors have recognized that this circumstance can be advantageous in the removing of the first material. In the particle beam-based removal as described herein, what is typically required is a defined (local) gas concentration over a particular period of time, in order to allow the removal reaction to run in a defined manner. This is of increased importance especially in the case of use of a more complex gas mixture comprising at least two gases (e.g. the first gas and the second gas). This is associated with elevated demands on the maintenance of the defined (local) gas concentration. For example, it is possible here for an increased degree of (local) depletion of the second gas (and/or of the first gas) to occur within the working region, such that the removing of the first material can be influenced in an unwanted manner. The inventors have recognized here that the use of first and second molecules having similar dipole moments (as described herein) can imply similar adhesion properties of the first and second molecules on a surface. A similar probability of adhesion of the first and second molecules may arise here, which means that equivalent coverage of the surface with the first and second molecules can be enabled. In particular, it is possible in this way to cover the surface of the first material with the first and second molecules in a defined manner in the removing operation. By means of this technical effect, it is accordingly possible to enable optimized conditions in the configuration of the defined (local) gas concentration in the use of the first and second gases. This mechanism of action can accordingly specifically optimize the removal of the first material.

As mentioned herein, the probability of adhesion of the molecules may be proportional to their dipole moment. Therefore, the method, in one example, comprises the inclusion of the first and second dipole moments of the first and second molecules (as described herein) as parameters in the removing of the first material. For example, the first and second dipole moments may define a process parameter (for example a gas flow rate of the first and/or second gas) in the removing operation.

In one example, the method comprises providing the first gas and the second gas at least partly simultaneously. For example, the first gas and the second gas may be introduced simultaneously into the environment of the working region or into the environment of the object, for example during the removal of the first material. This may also comprise the (at least partial) presence of a first gas volume flow rate of the first gas and of a second gas volume flow rate of the second gas during the removal, such that the presence of both gases in the environment of the working region/object is assured. It is possible here, for example, that the first and second gas volume flow rates are essentially identical. However, in other examples, they may also be different. The simultaneous provision of the first and second gases may also comprise variation of the first gas volume flow rate and of the second gas volume flow rate (in the removal of the first material).

In one example, the method comprises providing the first gas and the second gas at least partly with a time interval. For example, it may be necessary for the removal of the first material for only one of the two gases to be provided or introduced in the environment of the working region/object in a method step of removing. For example, it may be necessary at commencement of the removing of the first material for only the first gas (or the second gas) to be introduced at first into the environment of the working region/object. Subsequently, the second gas (or the first gas) may be fed in or provided at a later juncture. In addition, it is also conceivable that, during the removing, there is stepwise alternation between the (exclusive) providing/introducing of the first gas (without the second gas) and the (exclusive) providing/introducing of the second gas (without the first gas). Furthermore, it is also possible that an end of the process of removing the first material comprises the exclusive providing/introducing of one of the two gases. For example, it is conceivable that an end of the process of producing is defined by the exclusive providing/introducing of the second gas.

In one example, in the method in the first aspect, the second molecules comprise water, H₂O, and/or heavy water, D₂O. For the removal of the resistant first material, and also in relation to the selectivity of the removal of the first material, water and/or heavy water has been found to be an advantageous additive gas. In a particularly advantageous example, the method comprises NOCl as the first gas and H₂O as the second gas. In a further particularly advantageous example, the method comprises XeF₂ as the first gas and H₂O as the second gas. In a further example, the second molecules of the second gas may also comprise semi-heavy water, HDO.

In a further example, the second gas (or the second molecules) may comprise an oxygen-containing component, a halide and/or a reducing component. The same may apply to the herein described fourth gas (or the fourth molecules). The oxygen-containing component may include, for example, an oxygen-containing molecule. For example, the oxygen-containing component may comprise at least one of the following: oxygen (O₂), ozone (O₃), hydrogen peroxide (H₂O₂), dinitrogen monoxide (N₂O), nitrogen monoxide (NO), nitrogen dioxide (NO₂), nitric acid (HNO₃). The halide may include, for example, at least one of the following: Cl₂, HCl, XeF₂, HF, I₂, HI, Br₂, HBr, NOCl, NOF, ClNO₂, FNO₂, PCl₃, PCl₅. The reducing component may comprise a molecule having a hydrogen atom. For example, the reducing component may comprise at least one of the following: H₂, NH₃, CH₄.

In one example, in the method in the first aspect, the first material is removed selectively, such that a second material of the object is essentially not removed. For example, the method may be designed such that, in the removal according to the invention (for example based on particle beam-induced etching), there is selectivity of removal (for example etching selectivity) for the first material over the second material. The selectivity may enable, for example, removal of the second material at a lower removal rate than the first material when the second material is subjected to the method (as described herein). Accordingly, in the method, a defined selectivity is established (for example an elevated etching selectivity). This can be assured, for example, via a suitable choice of the first and/or second gas and suitable gas parameters of the first and/or second gas (e.g. gas mass flow rate, gas pressure, gas concentration, etc.). For example, it is especially possible to use the choice of the second gas (e.g. water and/or heavy water, as described herein) and the gas parameters of the second gas to adjust the selectivity of removal of the first material with respect to the second material. The method can also be carried out in such a way that there is essentially no physical/chemical stress on the second material.

In one example, the second material may comprise a material at any site on the lithography object, and also a material within the working region. Also conceivable as second material is a material that would in principle be subjected to the material-removing effect of the method. For example, this may comprise exposure of the second material to the first (or second) gas during the method and/or presence in the relatively close (or else immediate) environment of the particle beam. For example, the second material may adjoin the first material or be mechanically coupled to the first material (for example including indirectly via an intervening material). In this case, it is conceivable that the removing of the first material is associated with exposure of a surface of the second material, such that the second material would be subjected to the material-removing effect of the method. According to the invention, the removing of the second material can be counteracted via the selectivity of the method. The second material, in a typical application of the method, may, for example, be part of a layer of the object adjoining the first material (directly or indirectly). For example, the object may have a characteristic layer structure in which a cap layer adjoins a reflective layer stack (e.g. a Bragg mirror). The characteristic layer structure may also comprise a buffer layer adjoining the cap layer. There may additionally be an absorption layer adjoining the buffer layer. In one example, a portion of the absorption layer may comprise the first material (to be removed) in the method. The method may accordingly be configured with such a selectivity that the second material comprises the material of the buffer layer, the material of the cap layer and/or the material of the reflective layer stack. In one example, the selectivity is configured such that the second material explicitly comprises the material of the cap layer of the reflective layer stack of the object. This can enable controlled ending of the method via the reduced removal rate of the cap layer, without attacking the reflective layer stack. The cap layer may accordingly function as a removal stop (e.g. etching stop), such that it is possible to avoid damage to the reflective layer stack that would be associated with damage to the optical properties of the object.

The method can be carried out in that the selectivity of the removing of the first material with respect to the second material is at least 2:1. In one example, the selectivity of the removing of the first material with respect to the second material is at least 15:1, preferably at least 25:1, most preferably at least 50:1.

In one example, in the method in the first aspect, the method further comprises removing at least one intermediate material disposed between the first material and the second material. As described herein in relation to the characteristic layer structure, the intermediate material may comprise, for example, part of the buffer layer of the object. In addition, it is also conceivable that the at least one intermediate material comprises part of the buffer layer and part of the cap layer of the object. Notably, the intermediate material (to be removed) may comprise a part of a layer, which is between the first material and a material of the reflective layer stack of the object. For example, the characteristic layer structure may not necessarily comprise a cap layer or a buffer layer between the absorption layer and the reflective layer stack. For example, other types of intermediate materials (e.g., having other functions) may be present between the absorption layer and the reflective layer stack.

An intermediate material of an object for lithography may, for example, comprise the herein described properties of the first (or second) material. However, the intermediate material (to be removed) need not necessarily comprise the properties of the first material (or of the second material) that are specified herein.

In an example, the intermediate material may comprise tantalum. In such an example, the intermediate material may be considered as a tantalum-based material. For example, the intermediate material may comprise a tantalum compound (or may substantially be composed of tantalum).

For example, the intermediate material may comprise tantalum and one or more of the following: oxygen, nitrogen, carbon, boron, hydrogen. For example, the intermediate material may comprise tantalum and boron. For example, the intermediate material may comprise tantalum and nitrogen. For example, the intermediate material may comprise tantalum and oxygen. For example, the intermediate material may comprise tantalum, oxygen and boron.

In an example, the portion of the tantalum in the intermediate material may comprise at least 50 atomic percent or more. In an example, the portion of the tantalum in the intermediate material may comprise at least 70 atomic percent or more. For example, the portion of the tantalum in the intermediate material may be below 95 atomic percent. For example, the portion of the tantalum in the intermediate material may be between 50 atomic percent and 95 atomic percent.

For example, the intermediate material may comprise at least one of the following: TaBO, TaO, TaON, TaN, TaBN.

In an example of the method the method may comprise providing a third gas comprising third molecules, wherein the removing of the intermediate material is based at least partly on the third gas (and the provided particle beam). In an example, the third gas may be regarded as a main etching gas for the removal of the intermediate material (as described analogously herein for the first gas).

The herein described features of the first gas (or the first molecules) may, for example, apply to the third gas (or the third molecules), as well.

In an example, the first material and the intermediate material may be removed in a sequential manner (e.g., in a process comprising at least two steps).

For example, the method may comprise that in a first step the first material is removed (as described herein). To that regard, the first gas or the first gas in combination with the second gas may be provided. For the first step the intermediate material may, for example, function as a removal stop (e.g., an etch stop) for the removal of the first material.

Subsequently, in a further step the intermediate material may be removed with the third gas (as described herein). To that regard, the previously provided first gas (or the first gas and the second gas) may not be provided anymore. For example, it may be conceivable that the previously provided first gas (or the previously provided first and second gas) may be pumped out of the vicinity of the intermediate material. It may also be conceivable that a waiting time between the removal of the first material and the removal of the intermediate material is implemented. This may enable, that (substantially) the first gas (or the first and second gas) may not be present in the area of the particle beam induced reaction in a high concentration (e.g., compared to the concentration during the first step).

In an example, the method may further comprise providing a fourth gas comprising fourth molecules wherein the removal of the intermediate material is further based at least partly on the fourth gas. The herein described fourth gas may be regarded as an additive gas with respect to the third gas (as analogously described herein for the second gas).

The herein described features of the second gas (or the second molecules) may, for example, apply accordingly to the fourth gas (or the fourth molecules), as well.

In an example of the removal of the first material and the intermediate material the first molecules of the provided first gas to remove the first material may comprise chlorine. The third molecules of the provided third gas to remove the intermediate material may comprise fluorine, in that example. Hence, the first material may be processed with a chlorine-based chemistry, whereas the intermediate material may be processed with a fluorine-based chemistry. In such an example, the first molecules may, for example, comprise nitrosyl chloride (NOCl) and/or nitryl chloride (ClNO₂). In such an example, the third molecules may, for example, comprise xenon difluoride (XeF₂).

In an example of the removal of the first material and the intermediate material the first molecules of the provided first gas may comprise NOCl and the second molecules of the provided second gas may comprise water (H₂O) to remove the first material. The third molecules of the provided third gas may comprise XeF₂ and the fourth molecules of the provided fourth gas may comprise water, in that example. Hence, the first material may be removed with NOCl and H₂O, wherein the intermediate material may be removed with XeF₂ and H₂O.

In a further example, of the removal of the first material and the intermediate material the first gas may comprise NOCl and the second gas may comprise water (H₂O) to remove the first material, wherein the third gas may comprise XeF₂ and the fourth gas may comprise water and nitrogen dioxide (NO₂).

In an example, the herein described cap layer may comprise ruthenium. In such an example, the material of the cap layer may be regarded as a ruthenium-based cap layer. For example, the cap layer may be (substantially) composed out of ruthenium. For example, the cap layer may comprise a ruthenium compound. For example, the cap layer may comprise ruthenium and at least one of the following; Ti, Nb, Mo, Zr, Y, B, La, Co, Re (wherein the cap layer may further comprise nitrogen).

In one example, in the method in the first aspect, the method further comprises removing at least a surface material of the object. The surface material may comprise, for example, a material of the object having a surface accessible to the first gas and/or the second gas, and to the particle beam (for example an exposed surface of the object). The surface material may comprise any material, and is not restricted to the substances and proportions of substances of the first and second material as are specified herein. The surface material may be removed here, for example, in order to expose the first material disposed below it for the method according to the invention. In relation to the characteristic layer structure of the object as described herein, the surface material may, for example, be part of a surface layer adjoining the absorption layer (for example with respect to the buffer layer). The surface layer in this example may comprise an antireflection layer, an oxide layer, a passivation layer.

In one example, in the method in the first aspect, the particle beam is based at least partly on an acceleration voltage of less than 3 kV, preferably less than 1 kV, more preferably less than 0.6 kV. In these ranges of acceleration voltage, it is advantageously possible to remove the first material (as described herein).

In addition, it is also conceivable that the particle beam is based on an acceleration voltage of less than 30 kV, preferably less than 20 kV. In one example, an acceleration voltage between 3 kV and 30 kV may be employed for imaging purposes within the process (for example in the case of imaging before or after the removal and/or imaging during the removal).

In one example, the particle beam comprises a current between 1 pA and 100 pA, preferably between 5 pA and 80 pA, most preferably between 10 pA and 60 pA.

In an example, the particle beam may comprise a current between 50 pA and 100 pA. For example, the particle beam may comprise a current between 60 pA and 100 pA, 70 pA and 100 pA, 80 pA and 100 pA, or 90 pA and 100 pA.

In a further example, the particle beam may comprise a current between 100 pA and 200 pA. For example, the particle beam may comprise a current between 110 pA and 200 pA, 120 pA and 200 pA, 130 pA and 200 pA, 150 pA and 200 pA.

For example, the particle beam may comprise a current between 100 pA and 300 pA. For example, the particle beam may comprise a current between 110 pA and 300 pA, 150 pA and 300 pA, 200 pA and 300 pA, 250 pA and 300 pA.

In one example, in the method in the first aspect, the method further comprises determining an endpoint of the removing, based at least partly on detecting electrons that are released from the object. For example, the electrons may be released on account of an interaction of the particle beam provided with an object material or with a working region material. These may be electrons that exit from a region of action of the particle beam incident on the material, for physical reasons, on account of the particle beam. In one example, the electrons comprise scattered electrons and/or secondary electrons. The scattered electrons may comprise, for example, electrons backscattered by the object (backscattered electrons, i.e. BSE) and/or electrons forwardscattered by the object (forwardscattered electrons, i.e. FSE). The electrons detected may provide information about a material property in the region of action of the particle beam, which makes it possible to conclude the material processed by the particle beam. For example, the determining of the endpoint may comprise using the electrons detected to ascertain that the particle beam is not/no longer acting on the first material. This may indicate that the first material has been removed and the endpoint of the process (i.e. the end of the process) has been attained. In addition, the determining of the endpoint may comprise using the electrons detected to ascertain that the particle beam is processing the second material (not to be removed selectively) and the endpoint of the process has been attained. In principle, the electrons detected can be used to determine the material currently being processed by the particle beam without this being based on the determination of the endpoint (for example for process monitoring, as a protocol of the process history, etc.). The particle beam may also be configured such that there is a sufficient difference in signal of the electrons detected depending on the material in the region of action (for example via an acceleration voltage, current, etc.).

In one example, in the method in the first aspect, the particle beam comprises an electron beam. For example, the removing described herein, in the context of the method, may comprise electron beam-induced etching (also known, for example, as (F)EBIE—(focused) electron beam induced etching).

However, it is also conceivable that the particle beam comprises an ion beam (for example of gallium ions, helium ions, etc.). For example, the removing of the first material may be based on ion beam-induced machining/etching (e.g. focused ion beam (FIB) milling).

In addition, use of multiple particle beams as particle beam is also conceivable.

In one example, the method is carried out in such a way that a sidewall angle of the first material is 70° to 90°, preferably 74° to 90°, more preferably 78° to 90°, most preferably 80° to 90°. The sidewall angle may be based, for example, on the plane of a layer disposed beneath the first material, or else on the (planar) plane of the object.

In one example, the method is carried out in such a way that a surface of the second material has a square of the roughness, RMS, of less than 3 nm, preferably less than 2 nm, more preferably less than 1 nm, most preferably less than 0.5 nm.

In one example, the method in the first aspect is carried out in such a way that a defect of the object is repaired. For example, the method may comprise repairing an opaque defect of the object.

An opaque defect here is a faulty site on the lithography object that should actually not be opaque, i.e. clear, according to the design of the object (e.g. transparent or designed such that there is no specific absorption for a radiation of a particular wavelength, for example the lithography wavelength). A clear defect, by contrast, is a faulty site on the object for lithography that should actually be opaque according to the design of the object (e.g. non-transparent or strongly absorbing for a radiation of a particular wavelength, for example the lithography wavelength). In particular, opaque may be defined in relation to a lithography method for the object. For example, the object for lithography may comprise an EUV mask for an EUV lithography method, in which case “opaque” may refer to the lithography wavelength of 13.5 nanometers. It is also conceivable that “opaque” relates to a DUV lithography method (at a lithography wavelength, for example, of 193 nanometers or 248 nanometers), an i-line lithography method (at a lithography wavelength, for example, of 265 nanometers), or any other lithography method depending on the object. In addition, an opaque defect may comprise, for example, a faulty site having opaque material of a layer of a lithography mask (for example, this may comprise a layer designed as a layer for an opaque pattern element of the object). The method here may comprise removing the first material such that the faulty site is no longer opaque.

For example, the repair of the defect may comprise firstly localizing the defect (for example via a scanning electron microscope, an optical microscope, etc.). It is possible here to define the working region which is used for the removing of the first material on the basis of at least one characteristic of the localized defect (for example based on a position, shape, size, type of defect, etc.). The remedying of the defect in the object may further comprise producing a repair shape encompassing the defect. In one example, the repair shape may serve as the working region for the method specified herein. The repair shape may have, for example, a pixel pattern, which can enable localization of a defect site. The pixel pattern may, for example, be designed such that it follows the outline of the defect, such that every pixel in the pixel pattern corresponds essentially to a site in the defect and hence constitutes a defect pixel. In another example, the pixel pattern has a fixed geometric shape (e.g. a polygon, a rectangle, a circle, etc.) which fully encompasses the defect, in which case not every pixel necessarily constitutes a defect site. It is possible here for the pixel pattern to include defect pixels corresponding to a defect site, and non-defect pixels corresponding to a site which does not cover part of the defect. In one example, the method comprises directing the particle beam at least onto a defect pixel of the pixel pattern of the repair shape in the producing of the material. In addition, the particle beam may be configured such that it can be directed onto any defect pixel in the removing of the first material. This can ensure that the removing of the first material is locally restricted to the defect pixel and hence only the defect is processed.

In a further example, the method may be used in processing of the object which comprises local production of material. The processing, and the local production of material, can be carried out, for example, in the context of defect processing in the object (for example in a repair of a clear defect and/or a defective site, in a removal of a particle, etc.). Thus, the first material need not necessarily be a layer material of the object. The production of material may comprise, for example, the deposition of a material corresponding to the properties of the first material (as described herein). For example, in the course of local production of material, there may be incorrect production of the first material. Accordingly, by means of the method according to the invention, the incorrectly produced material may be removed as first material (as described herein). For example, it may also be necessary in the course of a complex repair to specifically produce the first material, and also to remove it in a controlled manner (for example, this may be necessary when the first material has been produced as a sacrificial layer).

In one example, in the method in the first aspect, the object comprises an EUV mask and/or a DUV mask. For example, the characteristic layer structure described here may correspond to a layer structure of an EUV mask.

A second aspect relates to an apparatus for processing an object for lithography, comprising: means of providing a first gas; means of providing a particle beam in a working region of the object, wherein the apparatus is configured to perform a method in the first aspect. In addition, the apparatus may comprise means of executing a computer program (e.g. a computer system, a computation unit, etc.). The apparatus may correspond essentially to a scanning electron microscope that can provide an electron beam as particle beam on the object. The scanning electron microscope may be configured such that it can provide the gases described herein. The first gas (and/or the second gas) may be stored, for example, in corresponding reservoir vessels and be guided via a gas supply system (e.g. a gas conduit with a gas nozzle) within the working region of the object.

A third aspect relates to an object for lithography, wherein the object has been processed by a method in the first aspect. It is possible here, for example, via an optical analysis of the object, to detect whether the object has been processed by a method in the first aspect. For example, for the lithography object, an optical analysis may initially have been conducted, or may be undertaken (for example in the course of defect qualification of the object, for example after production of the object and/or in the case of introduction of the object into a semiconductor works). The optical analysis may be based, for example, on an optical or particle-based microscope (for example on a mask metrology apparatus, a mask microscope) and, for example, an imaging operation. In the processing of the object in one example of the first aspect, after the initial analysis, the first material may have been removed as described herein. The removal of the first material can be detected via a repeated visual analysis (for example in the course of a repair check or another defect qualification). The detection may be carried out, for example, via a comparison of the initial visual analysis with the repeated visual analysis (for example via a comparison of the corresponding images). In addition, the detection in the method may also be based on a material analysis of the object (for example Auger spectroscopy, x-ray spectroscopy, etc.), which, for example, is executed in a supplementary manner with the initial or repeated visual analysis.

A fourth aspect relates to a method of processing a semiconductor-based wafer. The method in the fourth aspect further comprises lithographic transfer of a pattern associated with an object for lithography to the wafer, wherein the object has been processed according to one of the examples of the first aspect of the invention that have been given herein. The lithographic transfer may comprise a lithography method for which the object is designed (e.g. EUV lithography, DUV lithography, i-line lithography, etc.). For example, the method in the fourth aspect may comprise providing a beam source of electromagnetic radiation (e.g. EUV radiation, DUV radiation, i-line radiation, etc.). This may additionally include providing a developable lacquer layer on the wafer. The lithographic transfer may also be based at least partly on the radiation source and the providing of the developable lacquer layer. It is possible here, for example, by use of the radiation from the radiation source, to image the pattern onto the lacquer layer (in a transformed form).

The methods described herein may, for example, be recorded in written form. This can be achieved, for example, by use of a digital file, analogously (for example in paper form), in a user handbook, in a formula (recorded, for example, in a device and/or a computer at a semiconductor factory). It is also conceivable that a written protocol is compiled on execution of one of the methods described herein. The protocol may enable, for example, proof of the execution of the method and details thereof (for example the formula) at a later juncture (for example in the course of a fault assessment, a material review board, an audit, etc.). The protocol may comprise, for example, a protocol file (i.e. log file) which can be recorded, for example, in a device and/or computer.

A fifth aspect relates to a computer program comprising instructions which, when executed by a computer system, cause the computer system to implement a method according to the first aspect and/or a method according to the fourth aspect.

A further aspect relates to the aforementioned apparatus with a memory which comprises the computer program. Further, the apparatus may have a means for executing the computer program. Alternatively, it is also possible for the computer program to be stored elsewhere (e.g., in a cloud) and for the apparatus to merely have means for receiving instructions that arise from executing the program elsewhere. Either way, this may, for example, allow the method to run in automated or autonomous fashion within the apparatus. Consequently, it is possible to minimize the intervention, for example by an operator, and so it is possible to minimize both the costs and the complexity when processing masks.

The features (and also examples) of the methods that are specified herein may also be applied or applicable correspondingly to the apparatus mentioned, and also to the object mentioned. It is likewise possible for the features specified herein (and also examples) of the apparatus that are specified herein, and also the features (and also examples) of the object mentioned that are specified herein, to be applied or applicable correspondingly to the method described herein.

### BRIEF DESCRIPTION OF DRAWINGS

The following detailed description describes technical background information and working examples of the invention with reference to the figures, which show the following:

FIG. 1 gives a schematic illustration in a top view of an illustrative repair situation for an object for lithography from the prior art.

FIG. 2 shows a schematic diagram of an illustrative method of the invention.

FIGS. 3A-3C give a schematic illustration, in a cross section, by way of example, of operations in a method of the invention.

### DETAILED DESCRIPTION

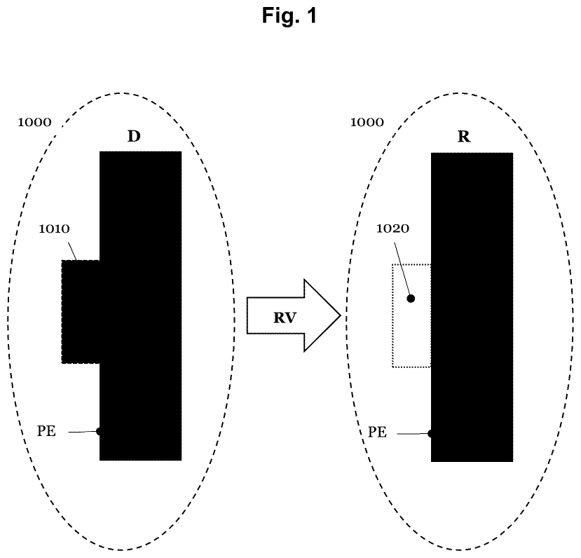

FIG. 1 gives a schematic illustration in a top view of an illustrative repair situation for an object for lithography. The object for lithography may comprise a lithographic mask suitable for any lithography method (e.g. EUV lithography, DUV lithography, i-line lithography, nanoimprint lithography, etc.). In one example, the lithography mask may comprise an EUV mask, a DUV mask, an i-line lithography mask and/or a nanoimprinting stamp. In addition, the object for lithography may comprise a binary mask (e.g. a chromium mask, an OMOG mask), a phase mask (e.g. a chromium-free phase mask, an alternating phase mask (e.g. a rim phase mask)), a half-tone phase mask, a tritone phase mask and/or a reticle (for example with pellicle). The lithography mask may be used, for example, in a lithography method for the production of semiconductor chips.

The object for lithography may comprise (unwanted) defects. For example, a defect may be caused in the production of the object. In addition, a defect may also be caused by (lithography) processing of the object, a process deviance in the (lithography) processing, transport of the object, etc. On account of the usually costly and complex production of an object for lithography, the defects are therefore usually repaired.

In the working examples described herein, for illustrative purposes, an EUV mask is frequently employed as an example of an object for lithography. However, rather than the EUV mask, any object for lithography is conceivable (for example as described herein).

FIG. 1 can show, in schematic form, in a top view, two local states D, R of a detail 1000 of an EUV mask in the course of a repair of a defect in the mask. The detail 1000 shows part of a pattern element PE of the EUV mask. The pattern element PE may also be regarded as a pattern element of the EUV mask. The pattern element PE may be part of a designed pattern which can be transferred to a wafer, for example, via a lithography method. The local state D shows an opaque defect 1010 adjoining the pattern element PE. The opaque defect 1010 may feature, for example, excess (opaque) material that should not be present at the defect site according to the mask design. The excess (opaque) material may correspond, for example, to an opaque material of the pattern element PE, or else to any other material of a layer of the pattern element PE (as described herein). In relation to FIG. 1 (state D), a defect-free pattern element PE in the detail 1000 would have to have a square shape, it being clear that this target state does not exist as a result of the opaque defect 1010. A repair procedure RV therefore typically removes the excess (opaque) material in the region of the opaque defect 1010, such that a repaired state R of the pattern element PE can be created. Thus, it is shown in state R that no opaque effect occurs any longer in the original defect region 1020 (i.e. at the original site in the opaque defect) and there is no longer any excess (opaque) material. The removal of the defect 1010 accordingly re-establishes the target state of the rectangular shape of the pattern element PE after a repair operation.

During use in lithography apparatuses or lithography methods, a lithography mask may be subject to extreme physical and chemical environmental conditions. This is especially true of the exposure of EUV masks (and also DUV masks, or other masks as described herein) during a corresponding lithography method, in which the opaque material in particular of a pattern element PE may be subjected to these influences to a significant degree. For example, in the case of EUV exposure, a hydrogen plasma comprising free hydrogen radicals may be released, which can attack the opaque material of the pattern element PE among other materials and cause a material-altering and/or -removing effect. Further damage influences may occur in the EUV lithography process and mask cleaning processes. Damage to the mask material includes, for example, a chemical and physical alteration of the material by (EUV) radiation, temperature, and also a reaction with hydrogen or another reactive hydrogen species (e.g. free radicals, ions, plasma, etc.). The alteration of the material may also be caused by a reaction with purge gases (e.g. N₂, extreme clean dry air-XCDA®, noble gases, etc.), in conjunction with the exposure radiation (e.g. EUV radiation, DUV radiation). The damage to the material may likewise arise or be enhanced by downstream processes (for example a mask cleaning operation). The downstream processes may, for example, additionally attack the opaque material of the pattern element PE that has previously been damaged by chemical/physical reactions during the exposure operation, and hence worsen the damage.

In general, therefore, the material properties of an EUV mask, especially the opaque material of the EUV mask (or of the pattern element PE), are therefore designed to be resistant to the aggressive physical/chemical conditions in lithography, in order to specifically counteract the material-removing effects. The specific opaque material used here in a pattern element PE may be a chemically resistant material. In particular, it is possible to employ chromium nitride-containing materials, and also chromium-containing materials having a high nitrogen content (as described herein), on account of their very high chemical stability, as resistant material in an EUV mask. The chromium nitride-containing materials may take the form, for example, of CrₐN_{b}Z_{c} (a, b>0, c≥0, Z: one or more further elements). Z here may comprise a metal, nonmetal, semimetal, alkali metal (e.g. Li, Na, K, Rb, Cs). In addition, Z may comprise an alkaline earth metal (e.g. Be, Mg, Ca, Sr, Ba), a 3rd main group element (e.g. B, Al, Ga, In, Tl), a 4th main group element (e.g. C, Si, Ge, Sn, Pb), a 5th main group element (e.g. N, P, As, Sb, Bi). In addition, Z may comprise a chalcogenide (e.g. O, S, Se, Te), a halogen (e.g. F, Cl, Br, I) a noble gas (atom) (e.g. He, Ne, Ar, Kr, Xe), a transition group element (e.g. Ti, Hr, Hf, V, Nb, Ta, Cr, Mo, W, Mn, Re, Co, Rh, Ir, Ni, Pd, Pt, Cu, Ag, Au, Zn, Cd, Hg).

However, this type of resistant (opaque) material of a pattern element PE or of an EUV mask can make the repair operation RV of an opaque defect 1010 significantly more difficult since the repair operation is to specifically remove the resistant (opaque) material. In particular, this circumstance can make it more difficult to repair masks by use of electron beam-induced etching processes.

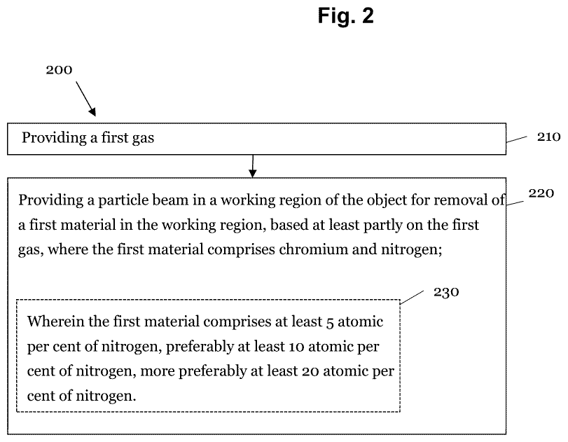

FIG. 2 shows a schematic diagram of an illustrative method 200 of the invention. The method 200 may be employed in order to remove material from an EUV mask. In particular, the method 200 may be employed in order to remove material from an opaque defect 1010 in the course of a repair operation.

The method 200 may comprise providing a first gas including first molecules. The first gas may comprise, for example, NOCl and/or XeF₂ as first molecules. In addition, other gases are also conceivable as first gas, as described herein.

Other molecules are also suitable as first molecules of the first gas for the method 200. For example, the first molecules may comprise molecules that may be regarded as acid halides of nitrogen-containing (e.g. inorganic) acids. The first molecules may likewise comprise molecules that can be split into chlorine radicals and nitrogen oxides under suitable reaction conditions and/or additionally, for example, a further nonpolar species. In addition, the first molecules may comprise molecules which, in aqueous solution, afford at least one of the following molecules: NO, HCl, HNO₂, HNO₃.

In addition, the method 200 may comprise providing 220 of a particle beam in a working region of the object for removal of a first material in the working region, based at least partly on the first gas. The first material here may comprise chromium and nitrogen. It may also be a characteristic 230 of the method 200 that the first material comprises at least 5 atomic percent of nitrogen, preferably at least 10 atomic percent of nitrogen, especially preferably at least 20 atomic percent of nitrogen. The method 200 may also comprise an electron beam as particle beam, such that electron beam-induced etching of the first material by the method 200 may be enabled.

The first material here may especially correspond to the resistant (opaque) material of the EUV mask (as described herein), which is to be removed in the course of the repair of an opaque defect.

The method 200 may also comprise providing a second gas as additive gas that assists the etching process (for example with regard to etch selectivity, etch rate, anisotropy factor, etc.). In particular, in the case of electron beam-induced etching, the first gas used in the method 200 may be NOCl and the additive gas H₂O (i.e. water (vapor)). It is likewise conceivable that, in the case of electron beam-induced etching, the first gas used in the method 200 may be XeF₂ and the additive gas H₂O (i.e. water (vapor)). In addition, the second molecules may comprise a dipole moment between 1.6 D and 2.1 D, preferably between 1.7 D and 2 D, more preferably between 1.8 D and 1.95 D, most preferably between 1.82 D and 1.9 D. It is likewise conceivable that the second molecules comprise at least one oxygen atom, but no nitrogen atom. In addition, the second molecules may comprise molecules which, on reaction with NOCl, afford at least one of the following molecules: NO, HCl, HNO₂, HNO₃.

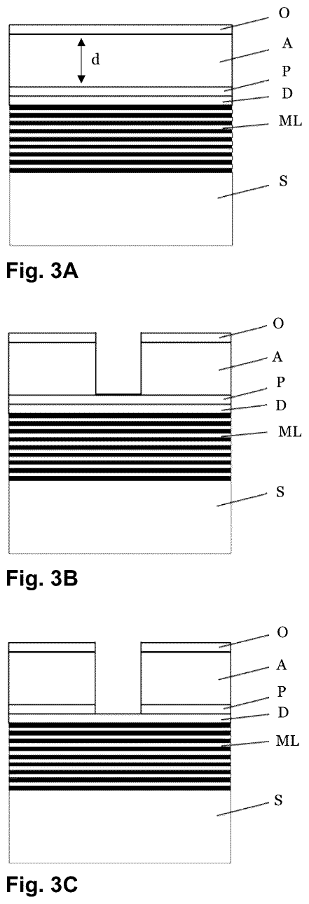

FIGS. 3A-3B give a schematic illustration, in a cross section, by way of example, of procedures in the method 200 that can take place in the course of repair of a defect in a lithography object.

FIG. 3A presents, in schematic form, an illustrative characteristic layer structure of a reflective lithography mask for the EUV wavelength region (i.e. an EUV mask). The illustrative EUV mask may be designed, for example, for an exposure wavelength in the region of 13.5 nm. The EUV mask may include a substrate S made of a material with a low coefficient of thermal expansion, for example quartz. Other dielectrics, glass materials or semiconducting materials likewise can be used as substrates for EUV masks.

The substrate S may be adjoined by a deposited multilayer film or a reflective layer stack ML including, for example, 20 to 80 pairs of alternating molybdenum (Mo) and silicon (Si) layers, which are also referred to as MoSi layers. The individual layers of the multilayer film ML may differ in refractive index, giving rise to a Bragg mirror that can reflect incident radiation (e.g. EUV radiation).

In order to protect the reflective layer stack ML, a cap layer D may be applied, for example, atop the uppermost layer of the reflective layer stack ML. The cap layer D may protect the reflective layer stack ML from damage by chemical processes during the production and/or during the use of the EUV mask (for example during a lithography method). The cap layer D may comprise ruthenium, and also elements or compounds of elements that increase reflectivity at wavelength 13.5 nm by not more than 3%. In addition, the cap layer D may comprise Rh, Si, Mo, Ti, TiO, TiO₂, ruthenium oxide, niobium oxide, RuW, RuMo, RuNb, Cr, Ta, nitrides, and also compounds and combinations of the aforementioned materials.

Atop the cap layer D there may be several layers that may include, for example, the layers of the pattern element (i.e. pattern element layers). The pattern element layers may comprise a buffer layer P, an absorption layer A and/or a surface layer O. The properties of the pattern element layers (for example an intrinsic material property of a pattern element layer, a layer thickness of a pattern element layer, etc.) and the geometry of the pattern element PE shaped therefrom may be designed to cause an opaque effect in relation to the exposure wavelength of the EUV mask. For example, the pattern element PE may be designed such that it is opaque (i.e. non-transparent to light or highly light-absorbing) with respect to light radiation having a wavelength of 13.5 nm. The pattern element layers may correspond to the layers of the opaque defect 1010, although the opaque defect 1010 need not necessarily have all the pattern element layers. For example, the opaque defect 1010 may have merely the buffer layer P and the absorption layer A.

The buffer layer P may be present atop the cap layer D. In addition, the absorption layer A may be present atop the buffer layer P. The absorption layer A may be designed to be effective in absorbing the radiation of lithography wavelengths (as described herein). Accordingly, the absorption layer A may make the main contribution to an opaque effect of the pattern element (or of the opaque defect 1010). The optical properties of the absorption layer A can be described, for example, by a complex refractive index that may include a phase shift contribution (i.e. n) and the absorption contribution (i.e. k). For example, n and k may be regarded as intrinsic material properties of the absorption layer. Only particular chemical elements and/or compounds of chemical elements have advantageous phase-shifting and/or absorptive properties for the corresponding lithography method (e.g. an EUV lithography method). FIG. 3A indicates, by way of example, the layer thickness d of the absorption layer A. The layer thickness d of the absorption layer A (and also a layer thickness of another layer of the mask) is ascertained, for example, along a normal vector in relation to the plane of the mask. In addition, the surface layer O may be present atop the absorption layer A. The surface layer O may comprise an anti-reflection layer, oxidation layer and/or passivation layer. As well as the absorption layer A, it is also possible for the buffer layer P and/or the surface layer O to contribute to the absorption and to the opaque effect of the pattern element PE or of the opaque defect 1010.

In principle, any of the pattern element layers described herein may include the resistant material mentioned (i.e. chromium nitride or chromium having a high nitrogen content). Typically, for example, the absorption layer A includes the (high) chromium nitride content or chromium with a high nitrogen content. In addition, however, it is alternatively possible, for example, for the buffer layer to have the (high) chromium nitride content or chromium with a high nitrogen content.

The first material in the method 200 may accordingly comprise a material of any pattern element layer. In particular, the first material in the method 200 may comprise the material of the absorption layer A.

FIG. 3B shows a result of an illustrative method 200 for removal of part of the absorption layer A. The absorption layer A is designed as the first material in the method 200. Initially, part of the surface layer O may first be removed. For example, this can be carried out analogously to the method 200 via electron beam-induced etching in a separate step. The surface layer need not necessarily be removed with the first and/or second gas (as described herein). It is also conceivable that the electron beam-induced etching is designed exclusively for the removing of the surface layer (for example with an etching gas matched to the material of the surface layer). After the surface layer O has been removed, it is then possible to remove part of the absorption layer A as the first material in the method 200 (for example to repair an opaque defect). FIG. 3B illustrates selective electron beam-induced etching of the absorption layer A with respect to the buffer layer P. Accordingly, the method 200 may be adjusted such that the etch rate of the absorption layer A is elevated compared to the etch rate of the buffer layer P. For example, the etching selectivity can be adjusted via the properties of the second gas in the method 200 (for example via a suitable choice of the second gas (e.g. water), or the gas flow rate of the second gas). In addition, the etch selectivity can also be adjusted by the properties of the first gas (for example via the choice of first gas) (e.g. NOCl or XeF₂), or via the gas flow rate of the first gas). In this example, the buffer layer P accordingly functions as etch stop via the etch selectivity chosen.

FIG. 3C shows a further result of an illustrative method 200 for removal of part of the absorption layer A. Initially, it is possible here (as described herein) to remove a portion of the surface layer O. After the surface layer O has been removed, it is then possible to remove part of the absorption layer A as the first material in the method 200. It is also possible here to etch a portion of the buffer layer P as intermediate material. Accordingly, the method 200 may be adjusted such that the etch rate of the absorption layer A, and also the etch rate of the buffer layer P, are elevated compared to the etch rate of the cap layer D. The etch rate of the absorption layer A may be in the same order of magnitude as the etch rate of the buffer layer P. The etch selectivity may be adjusted as described herein. As shown in FIG. 3C, this can achieve selective electron beam-induced etching of the absorption layer A and of the buffer layer P with respect to the cap layer D. In this example, the cap layer D therefore functions as etch stop via the etch selectivity chosen.

In one example, the surface layer O is not removed separately, but via the same process which is employed for the local removing of the absorption layer A (or of the absorption layer A and the buffer layer P) in a method 200.

In an example, the characteristic layer structure may comprise a ruthenium-based cap layer D and a tantalum-based buffer layer P (as described herein). In this example the characteristic layer structure may further comprise the absorption layer A (as described herein), wherein the absorption layer A may comprise the (herein described) first material. In such an example, the absorption layer A may comprise, for example, chromium and at least one atomic percent nitrogen (e.g., chromium nitride), the buffer layer P may comprise tantalum, the cap layer D may comprise ruthenium.

This exemplary characteristic layer structure may, for example, be processed sequentially with the herein described method (e.g., via two or more sub-processes).

For example, in a first step the absorption layer A may be locally removed with an electron beam induced process wherein NOCl is provided as a main etching gas and H₂O is provided as an additive gas. For example, the etching rate of this sub-process may be adapted such that the absorption layer A is etched with a higher etching rate than the buffer layer P. The buffer layer P may thus function as an etching stop for this sub-process wherein the buffer layer P may not be (substantially) removed during the first sub-process. Subsequently, the buffer layer P (comprising tantalum) may be locally removed with an electron beam induced process wherein XeF₂ is provided as a main etching gas and NO₂ and H₂O is provided (together) as an additive gas. For example, the etching rate of this sub-process may be adapted such that the buffer layer P is etched with a higher etching rate than the cap layer D. The cap layer D may thus function as an etching stop for this sub-process wherein the cap layer D may not be (substantially) removed during this sub-process.

In principle, it may also be necessary in a mask repair to produce or to deposit material (as repair material). In the case of mask repair by use of electron beam-induced deposition of chromium nitride (for example in the form of CrₐN_{b}Z_{c}, as described herein), chromium oxides or other chromium-containing deposits may also result in unwanted material deposition. Unwanted material deposition may be caused, for example, by off-target strands of the electron beam and secondary electrons generated thereby. In addition, unwanted deposition (of the repair material) may be caused by secondary electrons produced at sites adjacent to the repaired defect, and also by secondary electrons that escape at vertical edges of the processed material and propagate to sites adjacent to the repaired defect.

It is likewise possible for forwardscattered electrons (FSE) that escape from the flanks of existing material and backscattered electrons (BSE) that escape from the surface in the environment of the repaired site to contribute to unwanted material deposition.

A further application of the method 200 is therefore the removal of material that has been deposited by these mechanisms mentioned on areas adjacent to the repaired defect. In one example, the method 200 therefore also comprises the producing of a repair material.

In the course of production of the repair material, it is possible to use a deposition gas in the electron beam-induced deposition. It is possible here for at least one of the following to be included as deposition gas in the invention: (metal, transition element, main group) alkyls such as cyclopentadienyl (Cp) or methylcyclopentadienyl (MeCp) trimethylplatinum (CpPtMe₃ or MeCpPtMe₃), tetramethyltin SnMe₄, trimethylgallium GaMe₃, ferrocene Cp₂Fe, bisarylchromium Ar₂Cr and other compounds of this kind. In addition, at least one of the following may be included in the invention as first gas: (metal, transition element, main group) carbonyls such as chromium hexacarbonyl Cr(CO)₆, molybdenum hexacarbonyl Mo(CO)₆, tungsten hexacarbonyl W(CO)₆, dicobalt octacarbonyl Co₂(CO)₈, triruthenium dodecacarbonyl Ru₃(CO)₁₂, iron pentacarbonyl Fe(CO)₅ and other compounds of this kind. In addition, one of the following may be included in the invention as first gas:(metal, transition element, main group) alkoxides such as tetraethoxysilane Si(OC₂H₅)₄, tetraisopropoxytitanium Ti(OC₃H₇)₄ and other compounds of this kind.

It is also possible for at least one of the following to be included as deposition gas in the invention: (metal, transition element, main group) halides such as WF₆, WCl₆, TiCl₆, BCl₃, SiCl₄ and other compounds of this kind. In addition, at least one of the following may be included in the invention as deposition gas: (metal, transition element, main group) complexes such as copper bis(hexafluoroacetylacetonate) Cu(C₅F₆HO₂)₂, dimethylgold trifluoroacetylacetonate Me₂Au(C₅F₃H₄O₂) and other compounds of this kind. It is also possible for one of the following to be included as deposition gas in the invention: organic compounds such as CO, CO₂, aliphatic or aromatic hydrocarbons, constituents of vacuum pump oils, volatile organic compounds and further such compounds.

The method 200 (or the method in the first aspect) may be executed via the apparatus of the invention described herein. In one example, the apparatus comprises a mask repair apparatus for repair or processing of lithography masks. The apparatus may be used to localize and to repair or remedy mask defects. The apparatus may comprise parts such as the apparatus described in US 2020/0103751 A1 (see the corresponding FIG. 3A therein). The apparatus may comprise, for example, a control unit which may, for example, be part of a computer system. The apparatus, in one example, may be configured such that the computer system and/or the control unit controls the process parameters of the method in the first aspect as disclosed herein. This configuration can enable controlled, and also automated, implementation of the method according to the invention as specified herein, for example without manual interventions. This configuration of the apparatus can be achieved or enabled, for example, via the computer program according to the invention as described herein.

What is claimed is:

1. A method of processing an object for lithography, comprising:
providing a first gas comprising first molecules; and
providing a particle beam in a working region of the object for removal of a first material in the working region, based at least partly on the first gas;
wherein the first material comprises chromium and nitrogen,
wherein the first material comprises at least 1 atomic percent of nitrogen, and
wherein a sidewall angle of the first material is 70° to 90°.

2. The method according to claim 1, wherein the first material is capable of absorbing radiation associated with the object.

3. The method according to claim 1, wherein the first material corresponds to a layer material of a pattern element of the object.

4. The method according to claim 1, wherein the first material comprises a chromium nitride.

5. The method according to claim 1, wherein the first molecules comprise at least one halogen atom.

6. The method according to claim 1, wherein the first molecules comprise a halogen compound.

7. The method according to claim 6, wherein the halogen compound comprises a nitrosyl halide and/or a nitryl halide.

8. The method according to claim 7, wherein the nitrosyl halide comprises at least one of the following: nitrosyl chloride, NOCl, nitrosyl fluoride, NOF, nitrosyl bromide, NOBr; and/or
wherein the nitryl halide comprises at least one of the following: nitryl chloride, ClNO₂, nitryl fluoride, FNO₂.

9. The method according to claim 6, wherein the halogen compound comprises a noble gas halide.

10. The method according to claim 9, wherein the noble gas halide comprises at least one of the following: xenon difluoride, XeF₂, xenon dichloride, XeCl₂, xenon tetrafluoride, XeF₄, xenon hexafluoride, XeF₆.

11. The method according to claim 6, wherein the halogen compound comprises an interhalogen compound.

12. The method according to claim 1, wherein a first dipole moment associated with the first molecules comprises at least 1 D.

13. The method according to claim 1, wherein the method further comprises:
providing a second gas comprising second molecules, wherein the removing of the first material is further based at least partly on the second gas.

14. The method according to claim 13, wherein a first dipole moment associated with the first molecules and a second dipole moment associated with the second molecules differ from one another by not more than 0.1 D.

15. The method according to claim 13, wherein the second molecules comprise water, H₂O, and/or heavy water, D₂O.

16. The method according to claim 1, wherein the first material is removed selectively, such that a second material of the object is essentially not removed.

17. The method according to claim 16, wherein the method further comprises removing at least one intermediate material disposed between the first material and the second material.

18. The method according to claim 1, wherein the method further comprises removing at least one surface material of the object.

19. The method according to claim 1, wherein the particle beam is based at least partly on an acceleration voltage of less than 3 kV.

20. The method according to claim 1, wherein the method further comprises: determining an endpoint of the removing, based at least partly on detecting of electrons that are released from the object.

21. The method according to claim 1, wherein the particle beam comprises an electron beam.

22. The method according to claim 1, wherein the method is carried out in such a way that an opaque defect of the object is repaired.

23. The method according to claim 1, wherein the object comprises an EUV mask and/or a DUV mask.

24. An apparatus for processing an object for lithography, comprising:
a first gas outlet for providing a first gas; and
a particle beam source for providing a particle beam in a working region of the object, wherein the apparatus is configured to perform a method according to claim 1.

25. An object for lithography, wherein the object has been processed by a method according to claim 1.

26. A method of processing of a semiconductor-based wafer, comprising:
lithographic transfer of a pattern associated with an object for lithography to the wafer, wherein the object has been processed according to claim 1.

27. A computer program comprising instructions which, when they are executed by a computer system, cause the computer system to perform a method according to claim 1.
